(19) United States
(12) Patent Application Publication
(10) Pub. No.: US 2025/0338509 A1
(43) Pub. Date: Oct. 30, 2025

(54) SEMICONDUCTOR STRUCTURE AND MANUFACTURING METHOD FOR SEMICONDUCTOR STRUCTURE

(71) Applicant: Fujian Jinhua Integrated Circuit Co., Ltd., Fujian (CN)

(72) Inventors: Xuantong CHEN, Fujian (CN); Chien-Cheng Tsai, Fujian (CN); Yang ZHOU, Fujian (CN); Xianglong HE, Fujian (CN)

(73) Assignee: Fujian Jinhua Integrated Circuit Co., Ltd., Fujian (CN)

(21) Appl. No.: 18/783,360

(22) Filed: Jul. 24, 2024

(30) Foreign Application Priority Data
Apr. 30, 2024 (CN) 202410538397.3

(51) Int. Cl. H10B 63/00

(52) U.S. Cl. CPC H10B 63/845

(57) ABSTRACT

The present application provides a semiconductor structure and a manufacturing method for same. The semiconductor structure includes a substrate; a first stacked layer, disposed on the substrate; a first through structure, disposed in the first stacked layer, including a first sidewall structure and a first barrier layer disposed on the first sidewall structure; an isolation layer, disposed on the first stacked layer; a contact pad, disposed in the isolation layer and completely covering the first through structure; a second sidewall structure, disposed between the contact pad and the isolation layer; a second barrier layer, disposed on a sidewall and a bottom surface of the contact pad; a second through structure, disposed on the contact pad and at least partially in contact with the contact pad; where a width of a bottom surface of the contact pad is larger than a width of a top surface of the first through structure.

### CROSS-REFERENCE TO RELATED APPLICATIONS

This application claims priority to Chinese Patent Application No. 202410538397.3, filed on Apr. 30, 2024, which is hereby incorporated by reference in its entirety.

### TECHNICAL FIELD

The present application relates to the field of semiconductor technology and, in particular, to a semiconductor structure and a manufacturing method for the semiconductor structure.

### BACKGROUND

With the development of semiconductor memory devices, the demand for semiconductor memory devices with high-density data storage units is growing continuously. Therefore, a three-dimensional memory with multiple data storage unit layers stacked vertically has become a hot topic of research.

A three-dimensional memory includes a substrate and multiple stacked layer structures disposed on the substrate. For example, a first laminated layer structure and a second laminated layer structure are stacked on the substrate, and the first laminated layer structure located at the upper part includes a first through structure; and the second laminated structure located at the lower part includes a second through structure, and the top of the first through structure is in contact with and electrically connected to the bottom of the second through structure.

However, electrical connection reliability between the first through structure and the second through structure of the above three-dimensional memory is poor, which reduces the yield of the three-dimensional memory.

### SUMMARY

In view of the above problem, embodiments of the present application provide a semiconductor structure and a manufacturing method for the semiconductor structure, which can improve the yield of a three-dimensional memory.

In order to achieve the above purpose, the embodiment of the present application provides the following technical solution.

A first aspect of an embodiment of the present application provides a semiconductor structure, which includes a substrate; a first stacked layer, disposed on the substrate; a first through structure, disposed in the first stacked layer and including a first sidewall structure and a first barrier layer disposed on the first sidewall structure; an isolation layer, disposed on the first stacked layer; a contact pad, disposed in the isolation layer and completely covering the first through structure; a second sidewall structure, disposed between the contact pad and the isolation layer; a second barrier layer, disposed on a sidewall and a bottom surface of the contact pad; a second through structure, disposed on the contact pad and at least partially in contact with the contact pad; where a width of a bottom surface of the contact pad is larger than a width of a top surface of the first through structure.

In an embodiment, the first barrier layer is in contact with the first sidewall structure and part of the substrate, respectively; and the second barrier layer is in contact with the contact pad, the second sidewall structure and part of the first stacked layer, respectively.

In an embodiment, the first barrier layer and the second barrier layer are an integral structure.

In an embodiment, the first through structure further includes a first conductive plug, and the contact pad is at least partially contact with the first conductive plug.

In an embodiment, the contact pad and the first conductive plug are an integral structure.

In an embodiment, the first barrier layer is in contact with part of the bottom surface of the contact pad and the first conductive plug.

In an embodiment, the second through structure further includes a second conductive plug, and the contact pad is at least partially in contact with the second conductive plug.

In an embodiment, the first stacked layer includes dielectric layers and conductive layers disposed alternately.

In an embodiment, the first sidewall structure and the second sidewall structure includes the same material layer.

In an embodiment, the first sidewall structure and the second sidewall structure include a metal oxide layer and a third barrier layer disposed in sequence.

In an embodiment, the first through structure, the contact pad, and the second through structure are arranged in a staggered manner.

In an embodiment, the semiconductor structure further includes a second stacked layer, including dielectric layers and conductive layers disposed alternately; and the second through structure is located in the second stacked layer.

A second aspect of an embodiment of the present application provides a manufacturing method for semiconductor structure, including:
providing a substrate;
forming a first stacked layer on the substrate and an isolation layer covering the first stacked layer;
etching the isolation layer and the first stacked layer to form a first channel hole in the first stacked layer, respectively; and forming a groove connected to the first channel hole in the isolation layer, where a width of a bottom surface of the groove is larger than a width of a top surface of the first channel hole;
forming a sidewall layer in the first channel hole and the groove;
etching the sidewall layer to form a first sidewall structure disposed in the first channel hole and a second sidewall structure disposed in the groove;
forming a barrier material layer in the groove and the first channel hole, where the barrier material layer covers the first sidewall structure, the second sidewall structure and part of the first stacked layer exposed in the groove;
forming a contact pad and a first conductive plug in the groove and the first channel hole, respectively, where the first conductive plug, part of the barrier material layer and the first sidewall structure constitute a first through structure, the contact pad completely covers the first through structure, and a width of a bottom surface of the contact pad is larger than a width of a top surface of the first through structure;
forming a second stacked layer on the first stacked layer, where the second stacked layer includes a second through structure in contact with part of the contact pad.

In an embodiment, the etching the isolation layer and the first stacked layer further includes:
forming a first mask pattern on the isolation layer;
etching the isolation layer and the first stacked layer by using the first mask pattern, and forming a first channel hole;
etching the first mask pattern and forming a second mask pattern;
etching the isolation layer by using the second mask pattern to form the groove connected with the first channel hole in the isolation layer.

In an embodiment, the etching the sidewall layer further includes:
etching part of the sidewall layer located at the bottom of the first channel hole to expose part of the substrate in the first channel hole;
etching part of the sidewall layer located at the bottom of the groove to expose part of the first stacked layer in the groove, and to form the first sidewall structure and the second sidewall structure which are not in contact with each other.

In an embodiment, the forming the barrier material layer in the groove and the first channel hole includes: depositing and forming the barrier material layer in the groove and the first channel hole, where the barrier material layer covers the first sidewall structure, the second sidewall structure, the substrate partially exposed in the channel hole and the first stacked layer partially exposed in the groove.

In an embodiment, the barrier material layer further includes a first barrier layer covering the first sidewall structure and a second barrier layer covering the second sidewall structure.

In an embodiment, the forming the sidewall layer in the first channel hole and the groove further includes: depositing and forming a metal oxide layer and a third barrier layer in the first channel hole and the groove in sequence, where the metal oxide layer and the third barrier layer constitute the sidewall layer.

In an embodiment, the first through structure, the contact pad, and the second through structure are arranged in a staggered manner.

In an embodiment, the first conductive plug is in contact with the first barrier layer and the contact pad.

In an embodiment, the second through structure further includes a second conductive plug, and the contact pad is at least partially in contact with the second conductive plug.

Compared with the related art, the semiconductor structure and the manufacturing method for the semiconductor structure provided in the embodiments of the present application have the following advantages.

In the semiconductor structure and the manufacturing method for the semiconductor structure provided in the embodiments of the present application, the semiconductor structure includes the first stacked layer, the first through structure and the second through structure. The first through structure is disposed in the first stacked layer, and the top of the first through structure has the contact pad that completely covers it, and the width of the bottom surface of the contact pad is larger than the width of the top surface of the first through structure.

Further, the second barrier layer is disposed around the contact pad, which is isolated from the first sidewall structure, the second sidewall structure and part of the first stacked layer by the second barrier layer. The second through structure is located above the contact pad and is electrically connected to the contact pad, that is, the first through structure and the second through structure are electrically connected through the contact pad.

In the related art, the first through structure and the second through structure of a three-dimensional memory are prone to dislocation, resulting in a small contact area between the first through structure and the second through structure, or even no contact area therebetween, which affects the electrical connection reliability of the first through structure and the second through structure.

However, in the semiconductor structure provided by the embodiment of the present application, the width of the bottom surface of the contact pad is larger than the width of the top surface of the first through structure, so that the contact area between the first through structure and the second through structure can be increased, the poor electrical connection reliability between the first through structure and the second through structure can be improved, and then the yield of the three-dimensional memory can be improved.

In addition to the technical problems solved by the embodiments of the present disclosure, the technical features that constitute the technical solutions, and the beneficial effects brought about by the technical features of these technical solutions described above, other technical problems that can be solved by the semiconductor structure and the manufacturing method thereof provided by the embodiments of the present disclosure, other technical features included in the technical solutions, and the beneficial effects brought about by these technical features will be further described in detail in the “DESCRIPTION OF EMBODIMENTS”.

### BRIEF DESCRIPTION OF DRAWINGS

In order to more clearly illustrate the embodiments of the present application or the technical solutions in the prior art, the following is a brief introduction to the drawings required for use in the embodiments or the description of the prior art. Obviously, the drawings described below are some embodiments of the present application. For ordinary skill in the art, other drawings can be obtained based on these drawings without paying any creative effort.

FIG. 1 is a first schematic structural diagram of a semiconductor structure provided by an embodiment of the present application.

FIG. 2 is a flowchart of a manufacturing method for a semiconductor structure provided by an embodiment of the present application.

FIG. 3 is a detailed flowchart of step S300 in the manufacturing method for a semiconductor structure provided by an embodiment of the present application.

FIG. 4 to FIG. 15 are schematic diagrams of structures corresponding to each step of the manufacturing method for a semiconductor structure provided by an embodiment of the present application.

FIG. 16 is a second schematic structural diagram of a semiconductor structure provided by an embodiment of the present application.

### ILLUSTRATION OF THE REFERENCE NUMBERS

10—substrate;
11—etch stopping layer;
20—first stacked layer;
21—dielectric layer;
22—conductive layer;
23—first channel hole;
30—isolation layer;
31—groove;
40—mask layer;
41—first mask pattern;
42—second mask pattern;
50—sidewall layer;
50a—first sidewall structure;
50b—second sidewall structure;
51—metal oxide layer;
52—third barrier layer;
60—barrier material layer;
61—first barrier layer;
62—second barrier layer;
70—first through structure;
71—first conductive plug;
72—contact pad;
80—second stacked layer;
90—second through structure;
91—second conductive plug;
100—semiconductor structure.

### DESCRIPTION OF EMBODIMENTS

As for a three-dimensional memory in the related art, electrical connection reliability between a first through structure and a second through structure of the above three-dimensional memory is poor, leading to a problem of low yield of the three-dimensional memory. According to the research of the inventors, reasons for this problem are as follows.

The three-dimensional memory generally includes a substrate and a first laminated layer structure and a second laminated layer structure stacked in sequence, where the first laminated layer structure includes a first through structure; the second laminated layer structure includes a second through structure, and the top of the first through structure is in contact with and electrically connected to the bottom of the second through structure. However, the first through structure and the second through structure are prone to misalignment during the manufacturing process, resulting in a small contact area between the first through structure and the second through structure, or even no contact area therebetween, which affects the electrical connection reliability of the first through structure and the second through structure.

In view of the above technical problem, an embodiment of the present application provides a semiconductor structure and a manufacturing method for the semiconductor structure. By providing a contact pad that completely covers the top of the first through structure, and a width of a bottom surface of the contact pad is larger than a width of a top surface of the first through structure, a second barrier layer is disposed around the contact pad, which is insulated from the first sidewall structure, the second sidewall structure and part of the first stacked layer through the second barrier layer. The second through structure is located above the contact pad and is electrically connected with the contact pad.

In this way, in the semiconductor structure provided by the embodiment of the present application, the width of the bottom surface of the contact pad is larger than the width of the top surface of the first through structure, so that the contact area between the first through structure and the second through structure can be increased, the poor electrical connection reliability between the first through structure and the second through structure can be improved, and the yield of the three-dimensional memory can be further improved.

In order to make the above objectives, features and advantages of the embodiments of the present application more obvious and easy to understand, the technical solution in the embodiments of the present application will be described clearly and completely with the drawings. Obviously, the described embodiments are only part of the embodiments of present application, but not all the embodiments. Based on the embodiments in the present application, all other embodiments obtained by ordinary skill in the art without creative effort belong to the protection scope of the present application.

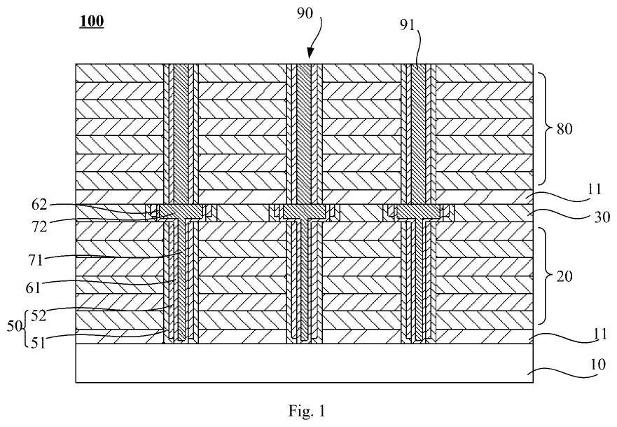

As shown in FIG. 1, a semiconductor structure 100 provided by an embodiment of the present application may be a three-dimensional memory, which includes a substrate 10, where the substrate 10 can be made of a semiconductor material. For example, the substrate 10 is made of materials including but not limited to silicon, germanium, silicon germanium, etc. In an implementation, the substrate 10 is made of single crystal silicon. Other semiconductor elements may be included in the substrate 10.

The substrate 10 is sequentially provided with a plurality of stacked layers. Illustratively, a first stacked layer 20 and a second stacked layer 80 are sequentially disposed on the substrate 10, that is, the second stacked layer 80 is located above the first stacked layer 20. The first stacked layer 20 and the second stacked layer 80 each include a plurality of dielectric layers 21 and a plurality of conductive layers 22 alternately disposed, and the thickness of the dielectric layer 21 and the thickness of the conductive layer 22 may be the same or different.

It should be noted that the conductive layer 22 is made of conductive materials. The conductive material used to make the conductive layer 22 includes, but not limited to, tungsten, copper, aluminum, doped silicon and/or silicide. The dielectric layer 21 is made of insulating material, and the insulating material for manufacturing the dielectric layer 21 includes but is not limited to silicon oxide, silicon nitride, silicon oxynitride or a combination of the above materials. Of course, more than three stacked layers can be stacked on the substrate 10 in sequence, which can be specifically disposed according to the number of conductive layers 22 actually stacked.

Each stacked layer is provided with a through structure. For example, the first stacked layer 20 is provided with a first through structure 70, where the first through structure 70 is disposed perpendicular to the first stacked layer 20, and the bottom end of the first through structure 70 extends to the surface of the substrate 10 or extends into the substrate 10.

The second stacked layer 80 is provided with a second through structure 90, where the second through structure 90 is disposed perpendicular to the second stacked layer 80, and the second through structure 90 is located above the corresponding first through structure 70. The second through structure 90 and the first through structure 70 are arranged in a staggered manner, and the bottom of the second through structure 90 is in contact with and electrically connected to the top of the corresponding first through structure 70.

For example, the first stacked layer 20 is provided with a first channel hole 23, the first channel hole 23 penetrates the first stacked layer 20, and the end of the first channel hole 23 closing to the substrate 10 can extend to the surface of the substrate 10 or the inside of the substrate 10. The first through structure 70 is disposed in the first channel hole 23. The first through structure 70 includes a first sidewall structure 50a, a first barrier layer 61 and a first conductive plug 71, where the first sidewall structure 50a is disposed on the inner sidewall of the first channel hole 23, the first barrier layer 61 is disposed on the inner sidewall of the first sidewall structure 50a, and surrounds the filling space of the first conductive plug 71. The first conductive plug 71 is inserted in the filling space surrounded by the first barrier layer 61, and the first conductive plug 71 is in contact with the first barrier layer 61. The bottom end of the first conductive plug 71 passes through the bottom of the first barrier layer 61, and contacts and electrically connects with the substrate 10.

Further, the surface of the first stacked layer 20 far from the substrate 10 is provided with the second stacked layer 80, and the second stacked layer 80 is provided with a second channel hole which penetrates through the second stacked layer 80. The second channel hole and the first channel hole 23 are arranged in a staggered manner, and the first channel hole 23 and the second channel hole are at least partially connected. The second through structure 90 is disposed in the second channel hole. The second through structure 90 has the same structure as that of the first through structure 70. For example, the second through structure 90 includes a second conductive plug 91. The second conductive plug 91 may be electrically connected to the first conductive plug 71, the details of which are not repeated here.

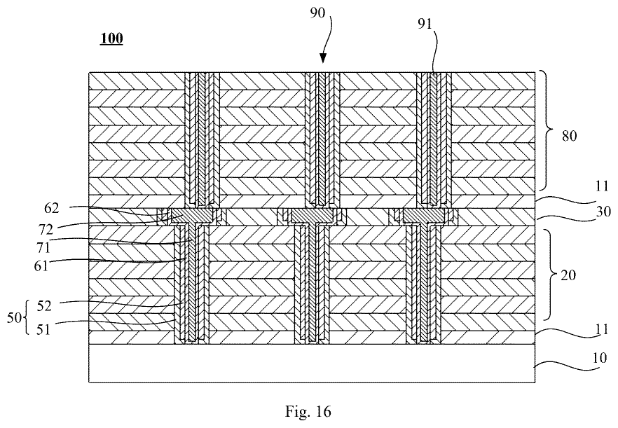

As shown in FIG. 16, the first through structure 70 and the second through structure 90 are disposed in a staggered manner in the embodiment of the present application. In order to ensure the electrical connection reliability of the first through structure 70 and the second through structure 90, the semiconductor structure 100 provided by the embodiment of the present application further includes an isolation layer 30 and a plurality of contact pads 72, where the plurality of contact pads 72 are disposed in the isolation layer 30 at intervals, each contact pad 72 is disposed on the top of the corresponding first through structure 70, and the contact pads 72 cover the top of the first through structure 70.

It can be understood that the semiconductor structure provided by the embodiment of the present application includes the first stacked layer 20 and the second stacked layer 80 located thereon, and the contact pad 72 is disposed at the top of the first through structure 70 and between the first stacked layer 20 and the second stacked layer 80, and the top of the second through structure 90 is not provided with the contact pad 72. In other words, when the semiconductor structure includes more than two stacked layers, a contact pad 72 may be provided between two adjacent stacked layers, and it is not necessary to provide the contact pad 72 on the stacked layer located at the top of the semiconductor structure.

Further, one side of the contact pad 72 is in contact with and electrically connected with at least part of the first conductive plug 71, and the other side of the contact pad 72 is electrically connected with at least part of the second conductive plug 91, that is, the contact pad 72 is used for electrically connecting the first through structure 70 and the second through structure 90. The second through structure 90 is disposed on the contact pad 72, and at least part of the second through structure 90 is in contact with the contact pad 72.

Illustratively, the isolation layer 30 is disposed on the surface of one side of the first stacked layer 20 away from the substrate 10, and covers the first stacked layer 20, that is, the isolation layer 30 is disposed between the first stacked layer 20 and the second stacked layer 80, and the isolation layer 30 has a certain thickness.

The isolation layer 30 in the embodiment of the present application may be made of the same material as that of the dielectric layer 21 of the first stacked layer. For example, the isolation layer 30 is made of insulating material, and the insulating material used to manufacture the isolation layer 30 includes but is not limited to silicon oxide, silicon nitride, silicon oxynitride, or a combination of the above materials.

The isolation layer 30 has a plurality of grooves 31, each of which is separately connected to a first channel hole 23. For example, the first channel hole 23 is centrally disposed with the corresponding groove 31. The width of the bottom surface of the groove 31 is greater than the size of the first channel hole 23, the bottom of the groove 31 is connected with the first channel hole 23, and a stepped hole structure is formed therebetween.

In the embodiment of the present application, a plurality of contact pads 72 are disposed in the isolation layer 30, and each contact pad 72 is disposed in a groove 31, respectively. The width of the bottom surface of the contact pad 72 is larger than the width of the top surface of the first through structure 70, and the contact pad 72 completely covers the first through structure 70, that is, the contact pad 72 completely covers the first conductive plug 71 and the end surface of the first sidewall structure 50a.

In order to keep the contact pad 72 being insulated from its surrounding structure, so as to prevent leakage current phenomenon from the contact pad 72 and the surrounding structure, the semiconductor structure 100 provided by the embodiment of the present application further includes a second barrier layer 62, where the second barrier layer may be a titanium nitride layer. The second barrier layer 62 is disposed on the sidewall and bottom surface of the contact pad 72 and surrounds the contact pad 72.

Further, the second barrier layer 62 is in contact with the first barrier layer 61, and the second barrier layer 62 and the first barrier layer 61 are an integral structure. The first barrier layer 61 is located between the first sidewall structure 50a and the first conductive plug 71, and the side parts of the first barrier layer 61 are in contact with the first sidewall structure 50a and the first conductive plug 71, respectively. The bottom of the first barrier layer 61 is in contact with the substrate 10.

Part of the second barrier layer 62 covers the inner surface of the second sidewall structure 50b and is located between the second sidewall structure 50b and the sidewall of the contact pad 72, that is, part of the second barrier layer 62 is in contact with the second sidewall structure 50b and the sidewall of the contact pad 72, respectively.

Part of the second barrier layer 62 covers the surface of the first stacked layer 20 exposed in the groove 31 and is located between the first stacked layer 20 and the bottom surface of part of the contact pad 72, that is, part of the second barrier layer 62 is in contact with part of the first stacked layer 20 and the bottom surface of part of the contact pad 72, respectively.

In the related art, the first through structure and the second through structure of the three-dimensional memory are prone to dislocation, resulting in a small contact area between the first through structure and the second through structure, or even no contact area therebetween, which affects the electrical connection reliability of the first through structure and the second through structure.

However, in the semiconductor structure 100 provided by the embodiment of the present application, the width of the bottom surface of the contact pad 72 is larger than the width of the top surface of the first through structure 70, so that the contact area between the first through structure 70 and the second through structure 90 can be increased, the poor electrical connection reliability between the first through structure 70 and the second through structure 90 can be improved, and then the yield of the three-dimensional memory can be improved.

On the basis of the above embodiment, the contact pad 72 and the first conductive plug 71 in the embodiment of the present application are configured as an integral structure. For example, both the first conductive plug 71 and the contact pad 72 are made of metal tungsten. In the preparation process, the first conductive plug 71 and the contact pad 72 are formed by a single deposition process to form the first conductive plug 71 and the contact pad 72 of an integrated structure. Such arrangement can improve the production efficiency and shorten the production cycle.

Further, the first sidewall structure 50a and the second sidewall structure 50b in the embodiment of the present application include the same material layer. For example, in the preparation process, the sidewall layer 50 with the same material layer can be formed by a single process. Such arrangement can improve the production efficiency and shorten the production cycle.

In an implementation, the first sidewall structure 50a and the second sidewall structure 50b include a metal oxide layer 51 and a third barrier layer 52 disposed in sequence. Where the manufacturing material of the metal oxide layer 51 includes but not limited to high-K dielectric materials. The third barrier layer 52 is made of the same material as that of the first barrier layer 61 and the second barrier layer 62, and both of them can be made of titanium nitride.

For example, in the first sidewall structure 50a, a metal oxide layer 51 is disposed on the inner wall of the first channel hole 23, and a third barrier layer 52 is disposed on the metal oxide layer 51. It can be understood that the second barrier layer 62 is disposed on the inner surface of the third barrier layer 52.

In the semiconductor structure 100 provided by the embodiment of the present application, the contact pad 72, the first through structure 70 and the second through structure 90 are disposed in a staggered manner. For example, in one implementation, the contact pad 72 is disposed directly opposite to the first through structure 70, and the second through structure 90 and the contact pad 72 are disposed in a staggered manner; or, in another implementation, the contact pad 72 and the first through structure 70 are disposed in a staggered manner, and the second through structure 90 and the contact pad 72 are disposed in a staggered manner, which is not limited in the embodiment of the present application.

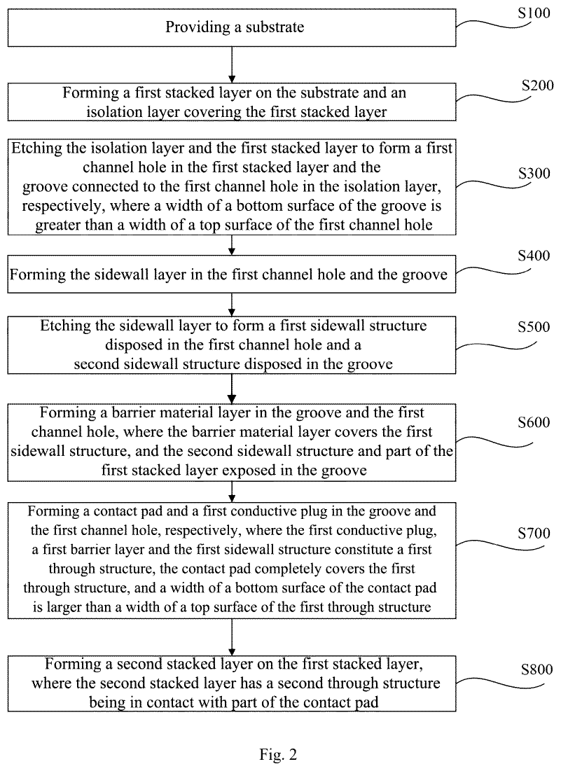

As shown in FIG. 2, an embodiment of the present application further provides a manufacturing method for the semiconductor structure 100, including the following steps.

First, step S100 is executed: providing a substrate 10; for example, the substrate 10 may be made of single crystal silicon to protect and support the first stacked layer 20 formed subsequently.

Next, step S200 is executed: forming a first stacked layer 20 and an isolation layer 30 covering the first stacked layer 20 on the substrate 10, and the structure formed in this step is shown in FIG. 4.

Specifically, before the first stacked layer 20 is formed on the substrate 10, an etch stopping layer 11 may be formed on the surface of the substrate 10. The etch stopping layer 11 is made of materials including but not limited to alumina. The etching selectivity ratio of the etch stopping layer 11 is different from that of the first stacked layer 20, that is, the etch stopping layer 11 can be used as a protective layer to control the etching speed and prevent the substrate 10 from being excessively etched when the first stacked layer 20 is subsequently etched to form the first channel hole 23.

After the etch stopping layer 11 is formed on the substrate 10, the first stacked layer 20 and the isolation layer 30 are sequentially formed on the etch stopping layer 11. Where the first stacked layer 20 includes dielectric layers 21 and conductive layers 22 alternately disposed in sequence, and the lowest dielectric layer 21 is in contact with the etch stopping layer 11.

The isolation layer 30 is located on the surface of the first stacked layer 20 away from the substrate 10. For example, the dielectric layer 21 of the uppermost first stacked layer 20 is configured as the isolation layer 30; or, insulating material is deposited on the dielectric layer 21 of the first stacked layer 20 to form the isolation layer 30, which is not limited in this embodiment. As follows, the dielectric layer 21 of the uppermost first stacked layer 20 being configured as the isolation layer 30 is taken as an example for explanation.

Illustratively, aluminum oxide is deposited on the substrate 10, and the etch stopping layer 11 is formed. Next, the insulating material and the conductive material are sequentially deposited on the etch stopping layer 11 to form the dielectric layer 21 and the conductive layer 22, respectively, where the conductive material includes but is not limited to tungsten, copper, aluminum, doped silicon and/or silicide. Insulating materials include, but are not limited to, silicon oxide, silicon nitride, silicon oxynitride or a combination of the above materials.

It should be noted that the isolation layer 30, as an insulating layer, can be made of the same material as that of the dielectric layer 21. Chemical vapor deposition (CVD), atomic layer deposition (ALD) or other suitable deposition methods can be used in the process of making the etch stopping layer 11, the dielectric layer 21 and the conductive layer 22, which is not limited in the embodiment of the present application.

Next, step S300 is executed: etching the isolation layer 30 and the first stacked layer 20 to form a first channel hole 23 in the first stacked layer 20 and the groove 31 connected to the first channel hole 23 in the isolation layer 30, respectively, where a width of a bottom surface of the groove 31 is greater than a width of a top surface of the first channel hole 23.

Specifically, the isolation layer 30 and the first stacked layer 20 are vertically etched for the first time to form a through hole penetrating through the first stacked layer 20 and the isolation layer 30. And one end of the through hole extends to the surface of the etch stopping layer 11, part of the through hole is located in the first stacked layer 20, and a first channel hole 23 is formed; and part of the through hole is located in the isolation layer 30. The groove 31 connected to the first channel hole 23 is subsequently configured, and this structure is shown in FIG. 7.

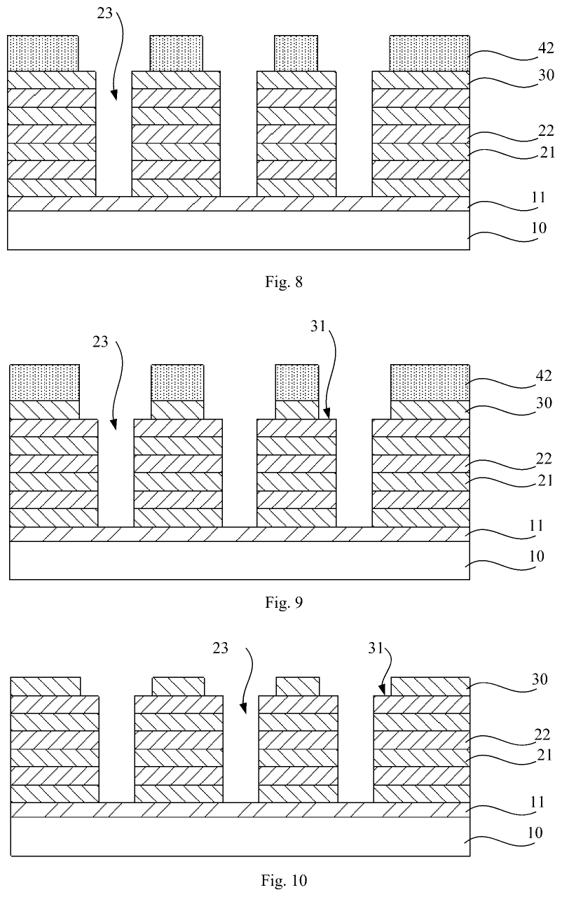

The isolation layer 30 is vertically etched for the second time to etch part of the isolation layer 30 around the through hole, to form the groove 31, where the width of the bottom surface of the groove 31 is larger than the width of the top surface of the first channel hole 23, in the isolation layer 30, and to form a stepped hole structure, as shown in FIG. 9.

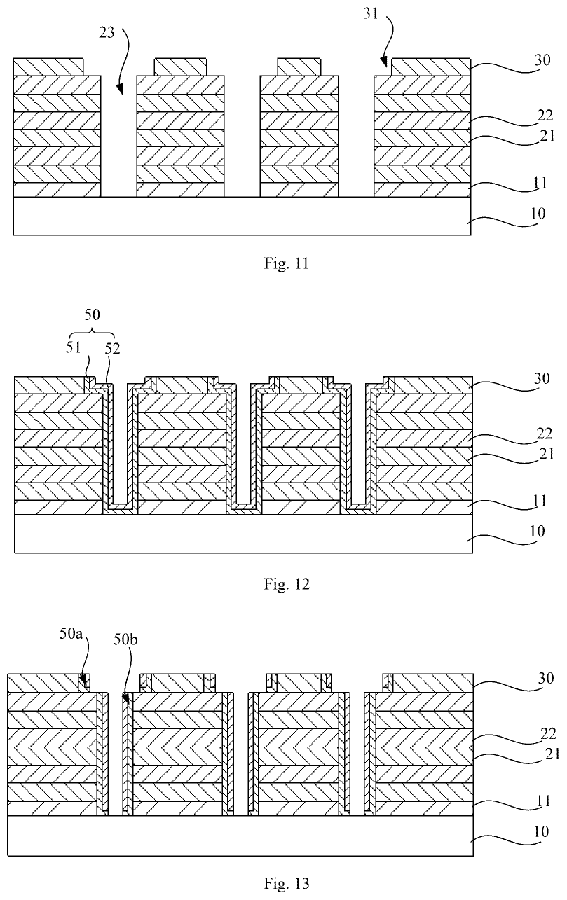

After the groove 31 is formed in the isolation layer 30, the etch stopping layer 11 is further etched so that the first channel hole 23 further extends to the surface or the inside of the substrate 10. This structure is shown in FIG. 11. It should be noted that a dry etching process can be used for the isolation layer 30 and the first stacked layer 20. A wet etching process can be used for the etch stopping layer 11, which is not limited in the embodiment of the present application.

After the first channel hole 23 and the groove 31 are formed, step S400 is executed: forming the sidewall layer 50 in the first channel hole 23 and the groove 31, and the structure formed in this step is shown in FIG. 12.

Specifically, the sidewall layer 50 includes a metal oxide layer 51 and a third barrier layer 52 which are sequentially disposed. High-K dielectric materials and titanium nitride are sequentially deposited in the first channel hole 23 and the first groove 31 to form the high-K dielectric layer and the titanium nitride layer, respectively, where the high-K dielectric layer is configured as the metal oxide layer 51, the titanium nitride layer is configured as the third barrier layer 52. The metal oxide layer 51 covers the inner wall of the first channel hole 23, and the third barrier layer 52 covers the metal oxide layer 51.

After the sidewall layer 50 is formed in the first channel hole 23 and the groove 31, step S500 is executed: etching the sidewall layer 50 to form a first sidewall structure 50a disposed in the first channel hole 23 and a second sidewall structure 50b disposed in the groove 31.

Specifically, the first channel hole 23 is used as an etching channel to etch and remove the third barrier layer 52 and the metal oxide layer 51 located at the bottom of the first channel hole 23, and part of the substrate 10 is exposed in the first channel hole 23. And, part of the sidewall layer 50 located at the bottom of the groove 31 is etched to expose part of the first stacked layer 20 in the groove 31, and to form a first sidewall structure 50a and a second sidewall structure 50b which are not in contact with each other. The structure formed by this step is shown in FIG. 13.

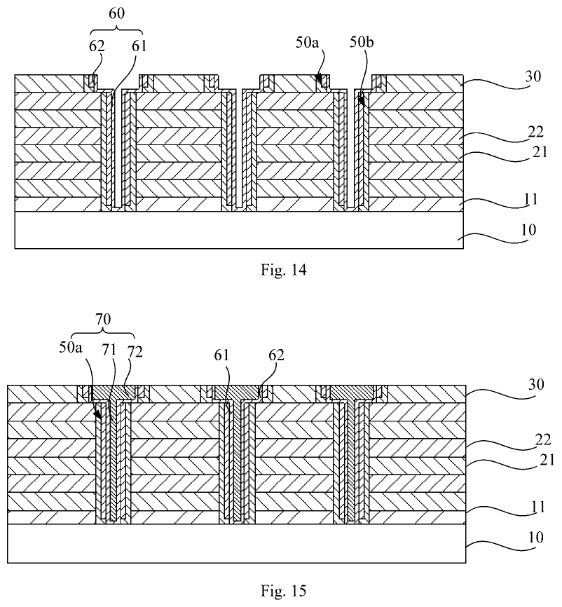

After the first sidewall structure 50a and the second sidewall structure 50b which are not in contact with each other are formed, step S600 is executed: forming a barrier material layer 60 in the groove 31 and the first channel hole 23, where the barrier material layer 60 covers the first sidewall structure 50a, the second sidewall structure 50b and part of the first stacked layer 20 exposed in the groove 31. The structure formed by this step is shown in FIG. 14.

Specifically, the groove 31 and the first channel hole 23 are used as a deposition channel, and titanium nitride is deposited to form a barrier material layer 60 which is continuous, and to cover the first sidewall structure 50a, the second sidewall structure 50b, the substrate 10 partially exposed to the first channel hole 23, and the first stacked layer 20 partially exposed in the groove 31.

It should be noted that the barrier material layer 60 further includes a first barrier layer 61 and a second barrier layer 62 in a continuous state, where the first barrier layer 61 covers the third barrier layer 52 of the first sidewall structure 50a and covers the substrate exposed in the first channel hole 23, and the second barrier layer 62 covers the second sidewall structure 50b and is exposed on the surface of the first stacked layer 20 in the groove.

After the barrier material layer 60 is formed in the first channel hole 23 and the groove 31, step S700 is executed: forming a contact pad 72 and a first conductive plug 71 in the groove 31 and the first channel hole 23, respectively, where the first conductive plug 71, the first barrier layer 61 and the first sidewall structure 50a constitute a first through structure 70, the contact pad 72 completely covers the first through structure 70, and the width of the bottom surface of the contact pad 72 is larger than the width of the top surface of the first through structure 70. The structure formed in this step is shown in FIG. 15.

Specifically, the first channel hole 23 and the groove 31 are used as a deposition channel, and metal tungsten is deposited in the first channel hole 23 and the groove 31. And then the first conductive plug 71 is formed in the first channel hole 23, the first barrier layer 61 surrounds and is in contact with the sidewall of the first conductive plug 71, and the bottom of the first conductive plug 71 is in contact with the first barrier layer 61. The first sidewall structure 50a, the first barrier layer 61 and the first conductive plug 71 constitute the first through structure 70.

A contact pad 72 is formed in the groove 31, where the contact pad 72 is located at the top of the first conductive plug 71, and both of them are an integral structure. Where the contact pad 72 completely covers the first through structure 70, and the width of the bottom surface of the contact pad 72 is larger than the width of the top surface of the first through structure 70.

Such arrangement can increase the contact area between the subsequent second through structure 90 and the contact pad 72. It should be noted that after the first conductive plug 71 and the contact pad 72 are formed, the top of the first through structure 70 can be mechanically polished to make the surface of the contact pad 72 away from the first conductive plug 71 flat.

After the contact pad 72 and the first conductive plug 71 are formed in the groove 31 and the first channel hole 23, respectively, step S800 can be executed: forming a second stacked layer 80 on the first stacked layer 20, where the second stacked layer 80 has a second through structure 90 being in contact with part of the contact pad 72, and the first through structure 70, the contact pad 72 and the second through structure 90 are disposed in a staggered manner. Further, the second through structure 90 includes a second conductive plug 91, and the second conductive plug 91 is at least partially in contact with the contact pad 72.

It should be noted that this step can refer to the example of the first stacked layer 20 and forming the first through structure 70 in the first stacked layer 20, which is not repeated here. The structure formed in this step is shown in FIG. 1. Here, it should be noted that the top of the second through structure 90 is not provided with the contact pad 72, therefore, the manufacturing of the contact pad 72 and related processes, such as the process of forming the groove on the top of the stacked layer, can be omitted.

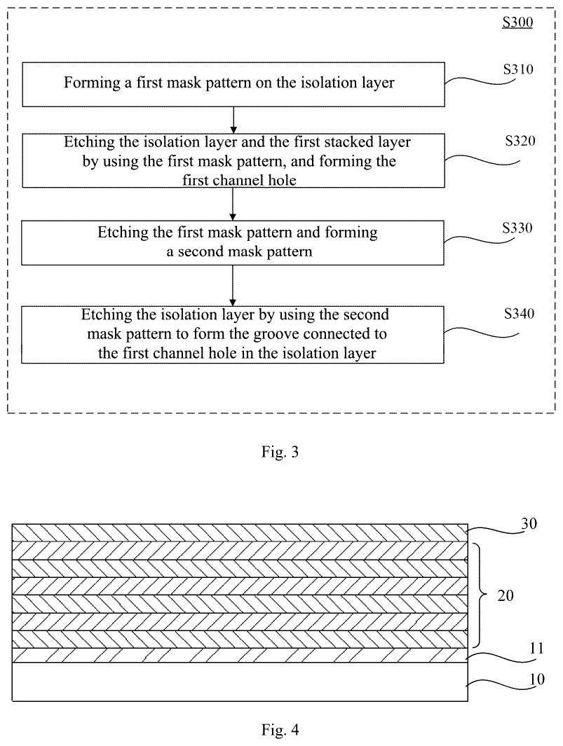

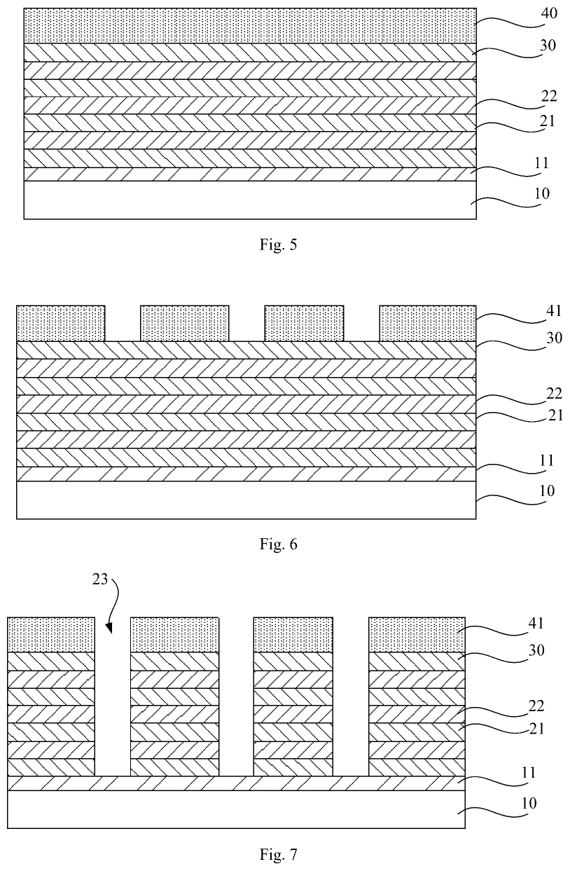

Based on the above embodiment, as shown in FIG. 3, in the manufacturing method provided by the embodiment of the present application, step S300: etching the isolation layer 30 and the first stacked layer 20 includes the following.
Step S310: forming a first mask pattern 41 on the isolation layer 30. Specifically, a mask layer 40 is formed on the isolation layer 30, and the mask layer 40 covers the isolation layer 30. The structure formed by this step is shown in FIG. 5. Further, the mask layer 40 is exposed and etched, and a first mask pattern 41 is formed on the isolation layer 30. The structure formed by this step is shown in FIG. 6.
Step S320: etching the isolation layer 30 and the first stacked layer 20 by using the first mask pattern 41, and forming the first channel hole 23.

Specifically, by using the first mask pattern 41 of the mask layer 40, the isolation layer 30 and the first stacked layer 20 are vertically etched, and this etching can be stopped at the etch stopping layer 11, thereby removing part of the isolation layer 30 and part of the first stacked layer 20 to form the first channel hole 23. The structure formed by this step is shown in FIG. 7.
Step S330: etching the first mask pattern 41 and forming a second mask pattern 42.

Specifically, the first mask pattern 41 is exposed and etched again to form a second mask pattern 42 on the isolation layer 30. The structure formed by this step is shown in FIG. 8.
Step S340: etching the isolation layer 30 by using the second mask pattern 42 to form the groove 31 connected to the first channel hole 23 in the isolation layer 30. The structure formed in this step is shown in FIG. 9.

Specifically, the isolation layer 30 is partially etched by using the second mask pattern 42 to form the groove 31 corresponding to the first channel hole 23 in the isolation layer 30, and the bottom of the groove 31 is connected to the first channel hole 23. In this way, the groove 31 and the first channel hole 23 are formed by two mask patterns, and the etching accuracy for etching the groove 31 and the first channel hole 23 can be ensured.

It should be noted that after completing step S340, the following is further included: removing the second mask pattern 42 located on the isolation layer 30. The structure formed by this step is shown in FIG. 10.

Each embodiment or implementation in this specification is described in a progressive manner, and each embodiment focuses on the differences from other embodiments. The same and similar parts between the embodiments can be referred to each other.

It should be noted that references to “one embodiment”, “embodiment”, “exemplary embodiment” and “some embodiments” in the specification mean that the described embodiments may include specific features, structures or characteristics, but not every embodiment necessarily includes the specific features, the structures or the characteristics. Moreover, such phrases do not necessarily refer to the same embodiment. In addition, when describing the specific features, the structures or the characteristics in conjunction with the embodiments, it is within the knowledge of those skilled in the art to realize such features, structures or characteristics in conjunction with other embodiments that are explicitly or implicitly described.

Finally, it should be illustrated that the above embodiments are only used to illustrate the technical solutions of the present application, rather than limiting them. Although the present application has been described in detail with reference to the foregoing embodiments, it should be understood by those of ordinary skill in the art that the technical solution described in the foregoing embodiments can be still modified, or some or all of the technical features thereof can be substituted by equivalents. And these modifications or substitutions do not make the essence of the corresponding technical solutions deviate from the scope of the technical solutions of various embodiments of present application.

What is claimed is:

1. A semiconductor structure, comprising:
a substrate;
a first stacked layer, disposed on the substrate;
a first through structure, disposed in the first stacked layer and comprising a first sidewall structure and a first barrier layer disposed on the first sidewall structure;
an isolation layer, disposed on the first stacked layer;
a contact pad, disposed in the isolation layer and completely covering the first through structure;
a second sidewall structure, disposed between the contact pad and the isolation layer;
a second barrier layer, disposed on a sidewall and a bottom surface of the contact pad;
a second through structure, disposed on the contact pad and at least partially in contact with the contact pad; wherein a width of a bottom surface of the contact pad is larger than a width of a top surface of the first through structure.

2. The semiconductor structure according to claim 1, wherein the first barrier layer is in contact with the first sidewall structure and part of the substrate, respectively;
the second barrier layer is in contact with the contact pad, the second sidewall structure and part of the first stacked layer, respectively.

3. The semiconductor structure according to claim 1, wherein the first barrier layer and the second barrier layer are an integral structure.

4. The semiconductor structure according to claim 1, wherein the first through structure further comprises a first conductive plug, and the contact pad is at least partially contact with the first conductive plug.

5. The semiconductor structure according to claim 4, wherein the contact pad and the first conductive plug are an integral structure.

6. The semiconductor structure according to claim 4, wherein the first barrier layer is in contact with part of the bottom surface of the contact pad and the first conductive plug, respectively.

7. The semiconductor structure according to claim 1, wherein the second through structure further comprises a second conductive plug, and the contact pad is at least partially in contact with the second conductive plug.

8. The semiconductor structure according to claim 1, wherein the first stacked layer comprises dielectric layers and conductive layers disposed alternately.

9. The semiconductor structure according to claim 1, wherein the first sidewall structure and the second sidewall structure comprise the same material layer.

10. The semiconductor structure according to claim 9, wherein the first sidewall structure and the second sidewall structure comprise a metal oxide layer and a third barrier layer disposed in sequence.

11. The semiconductor structure according to claim 1, wherein the first through structure, the contact pad, and the second through structure are arranged in a staggered manner.

12. The semiconductor structure according to claim 1, wherein the semiconductor structure further comprises:
a second stacked layer, comprising dielectric layers and conductive layers disposed alternately; and the second through structure is located in the second stacked layer.

13. A manufacturing method for a semiconductor structure, comprising:
providing a substrate;
forming a first stacked layer on the substrate and an isolation layer covering the first stacked layer;
etching the isolation layer and the first stacked layer to form a first channel hole in the first stacked layer, respectively; and forming a groove connected to the first channel hole in the isolation layer, wherein a width of a bottom surface of the groove is larger than a width of a top surface of the first channel hole;
forming a sidewall layer in the first channel hole and the groove;
etching the sidewall layer to form a first sidewall structure disposed in the first channel hole and a second sidewall structure disposed in the groove;
forming a barrier material layer in the groove and the first channel hole, wherein the barrier material layer covers the first sidewall structure, the second sidewall structure and part of the first stacked layer exposed in the groove;
forming a contact pad and a first conductive plug in the groove and the first channel hole, respectively, wherein the first conductive plug, part of the barrier material layer and the first sidewall structure constitute a first through structure, the contact pad completely covers the first through structure, and a width of a bottom surface of the contact pad is larger than a width of a top surface of the first through structure;
forming a second stacked layer on the first stacked layer, wherein the second stacked layer comprises a second through structure in contact with part of the contact pad.

14. The manufacturing method according to claim 13, wherein the etching the isolation layer and the first stacked layer further comprises:
forming a first mask pattern on the isolation layer;
etching the isolation layer and the first stacked layer by using the first mask pattern, and forming a first channel hole;
etching the first mask pattern and forming a second mask pattern;
etching the isolation layer by using the second mask pattern to form the groove connected with the first channel hole in the isolation layer.

15. The manufacturing method according to claim 13, wherein the etching the sidewall layer further comprises:
etching part of the sidewall layer located at the bottom of the first channel hole to expose part of the substrate in the first channel hole;
etching part of the sidewall layer located at the bottom of the groove to expose part of the first stacked layer in the groove, and to form the first sidewall structure and the second sidewall structure which are not in contact with each other.

16. The manufacturing method according to claim 15, wherein the forming the barrier material layer in the groove and the first channel hole comprises:
depositing and forming the barrier material layer in the groove and the first channel hole, wherein the barrier material layer covers the first sidewall structure, the second sidewall structure, the substrate partially exposed in the channel hole and the first stacked layer partially exposed in the groove.

17. The manufacturing method according to claim 16, wherein the barrier material layer further comprises a first barrier layer covering the first sidewall structure and a second barrier layer covering the second sidewall structure.

18. The manufacturing method according to claim 13, wherein the forming the sidewall layer in the first channel hole and the groove further comprises:
depositing and forming a metal oxide layer and a third barrier layer in the first channel hole and the groove in sequence, wherein the metal oxide layer and the third barrier layer constitute the sidewall layer.

19. The manufacturing method according to claim 13, wherein the first through structure, the contact pad, and the second through structure are arranged in a staggered manner.

20. The manufacturing method according to claim 17, wherein the first conductive plug is in contact with the first barrier layer and the contact pad.
